(19) United States
(12) Patent Application Publication
(10) Pub. No.: US 2024/0387368 A1
(43) Pub. Date: Nov. 21, 2024

(54) SEMICONDUCTOR DEVICE AND METHOD OF MANUFACTURE

(71) Applicant: Taiwan Semiconductor Manufacturing Co., Ltd., Hsinchu (TW)

(72) Inventors: Chin-Yi Lin, Taichung (TW); Jie Chen, New Taipei City (TW); Sheng-Han Tsai, Hsinchu (TW); Yuan Sheng Chiu, Miaoli (TW); Chou-Jui Hsu, Taoyuan (TW); Yu Kuei Yeh, New Taipei City (TW); Tsung-Shu Lin, New Taipei City (TW)

(21) Appl. No.: 18/788,881

(22) Filed: Jul. 30, 2024

Related U.S. Application Data
(62) Division of application No. 17/819,381, filed on Aug. 12, 2022.
(60) Provisional application No. 63/364,041, filed on May 3, 2022.

(51) Int. Cl. H01L 23/528; H01L 23/00; H01L 23/532

(52) U.S. Cl. CPC H01L 23/528; H01L 23/53209; H01L 24/27; H01L 24/33; H01L 2224/33104

(57) ABSTRACT

A semiconductor device and method of manufacture are presented in which a first pad and a second pad are formed adjacent to each other. A first set of dummy pads is manufactured between the first pad and the second pad and bonding pads are formed in electrical connection to the first pad and the second pad.

### PRIORITY CLAIM AND CROSS-REFERENCE

This application is a divisional of U.S. patent application Ser. No. 17/819,381, entitled, “Semiconductor Device and Method of Manufacture,” filed on Aug. 12, 2022, which claims priority to and the benefit of U.S. Provisional Application No. 63/364,041, filed on May 3, 2022, entitled “Semiconductor Structure,” which applications are hereby incorporated herein by reference in their entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a first semiconductor device bonded to a first wafer in accordance with some embodiments.

FIG. 2 illustrates an encapsulation of the first semiconductor device in accordance with some embodiments.

FIG. 3 illustrates a planarization process in accordance with some embodiments.

FIG. 4 illustrates a formation of a bonding layer in accordance with some embodiments.

FIG. 5 illustrates a placement of a second semiconductor device, a third semiconductor device, and a fourth semiconductor device in accordance with some embodiments.

FIG. 6 illustrates an encapsulation of the second semiconductor device, the third semiconductor device, and the fourth semiconductor device in accordance with some embodiments.

FIG. 7 illustrates a view of a first set of dummy pads in accordance with some embodiments.

FIG. 8 illustrates a view of the first set of dummy pads which utilize a discontinuous line in accordance with some embodiments.

FIG. 9 illustrates a view of the first set of dummy pads with circular pads in accordance with some embodiments.

FIG. 10 illustrates a view of the first set of dummy pads utilizing an “S”-shape in accordance with some embodiments.

FIG. 11 illustrates a placement of a fifth semiconductor device, a sixth semiconductor device, and a seventh semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to pad designs used to reduce bonding risks in bonding interfaces in structures such as system on integrated circuit (SoIC) devices. The embodiments presented, however, are not intended to be limiting to the ideas presented, as the ideas may be implemented in a wide array of embodiments, and all such embodiments are fully intended to be included within the scope of the current disclosure.

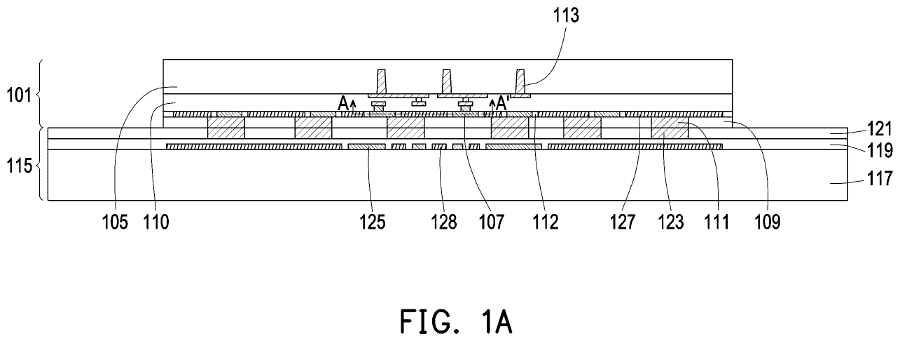

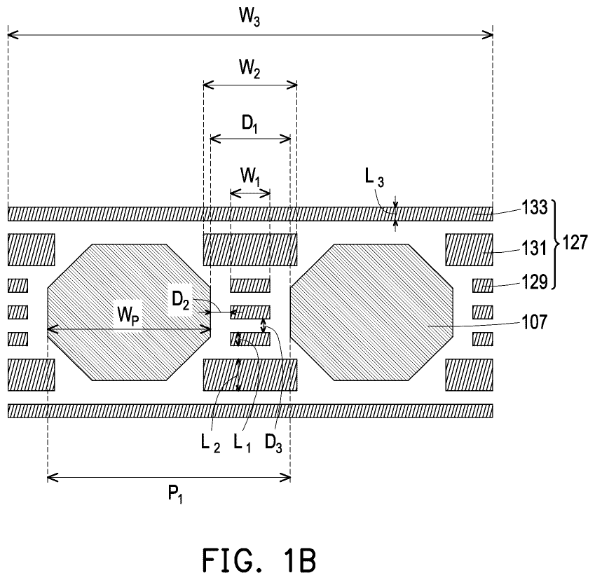

With respect now to FIG. 1A, there is illustrated a first semiconductor device 101 bonded to a first wafer 115. In an embodiment the first semiconductor device 101 may be a semiconductor device such as a memory device, a logic device, a power device, combinations of these, or the like, that is designed to work in conjunction with other devices. However, any suitable functionality may be utilized.

In an embodiment, the first semiconductor device 101 may comprise a first substrate 105, first active devices (not separately illustrated), first metallization layers 110, a first pad 107, a first set of dummy pads 127, a first bond layer 109, and first bonding metal 111 within the first bond layer 109. The first substrate 105 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The first active devices comprise a wide variety of active devices and passive devices such as capacitors, resistors, inductors and the like that may be used to generate the desired structural and functional requirements of the design for the first semiconductor device 101. The first active devices may be formed using any suitable methods either within or else on the first substrate 105.

The first metallization layers 110 are formed over the first substrate 105 and the first active devices and are designed to connect the various active devices to form functional circuitry. In an embodiment the first metallization layers 110 are formed of alternating layers of dielectric and conductive material and may be formed through any suitable process (such as deposition, damascene, dual damascene, etc.). In an embodiment there may be four layers of metallization separated from the first substrate 105 by at least one interlayer dielectric layer (ILD), but the precise number of first metallization layers 110 is dependent upon the design.

The first pads 107 and the first set of dummy pads 127 are formed within and/or over the first metallization layers 110. In an embodiment the first pads 107 and the first set of dummy pads 127 are formed of a conductive material such as an aluminum, copper, or an aluminum copper alloy (wherein the aluminum copper alloy may have any suitable weight-% of copper doping in the aluminum matrix), although other suitable materials, such as aluminum, copper, tungsten, composite layers of different materials, or the like, may be utilized. The material of the first pads 107 and the first set of dummy pads 127 may be formed using a process such as CVD or PVD. The material of the first pads 107 and the first set of dummy pads 127 may be deposited to a thickness of between about 14.5 μm and about 28 μm. However, any suitable material, process, and thickness may be utilized.

Once the material of the first pads 107 and the first set of dummy pads 127 has been deposited, the material of the first pads 107 and the first set of dummy pads 127 may be patterned into the desired shapes of the first pads 107 and the first set of dummy pads 127 (described further below). In an embodiment the material of the first pads 107 and the first set of dummy pads 127 may be patterned using, e.g., a photolithographic masking and etching process, whereby a photosensitive mask is placed and patterned, and then the photosensitive mask is used along with one or more etching processes in order to remove uncovered portions of the material of the first pads 107 and the first set of dummy pads 127. Once patterned, the photosensitive mask may be removed. However, any suitable process may be utilized.

Once the material of the first pads 107 and the first set of dummy pads 127 has been patterned, a first pad dielectric 112 may be deposited. In an embodiment the first pad dielectric 112 may be a dielectric material such as a low-k dielectric material, silicon dioxide, silicon nitride, silicon oxynitride, combinations of these, or the like, deposited using a method such as chemical vapor deposition, physical vapor deposition, atomic layer deposition, combinations of these, or the like. However, any suitable material and process may be utilized.

Once the first pad dielectric 112 has been deposited, the first pad dielectric 112 may be planarized with the first pads 107 and the first set of dummy pads 127. In an embodiment the first pad dielectric 112 may be planarized using a process such as chemical mechanical polishing. However, any other suitable planarization process may be utilized.

Additionally, while a particular process has been described in the preceding paragraphs to describe the formation of the first pads 107, the first set of dummy pads 127, and the first pad dielectric 112, the presented description is intended to be illustrative and is not intended to limit the embodiments. Rather, any suitable process steps or combination of process steps may be utilized. For example, in another embodiment, the first pad dielectric 112 may be deposited prior to formation of the first pads 107 and the first set of dummy pads 127. In this embodiment the first pad dielectric 112, once deposited, may then be patterned to form openings. Once the openings have been formed, the material for the first pads 107 and the first set of dummy pads 127 is deposited to fill and/or overfill the openings, and the material for the first pads 107 and the first set of dummy pads 127 is planarized in order to render the first pads 107 and the first set of dummy pads 127 planar with the first pad dielectric 112. Any suitable process may be utilized and all such processes are fully intended to be included within the scope of the embodiments.

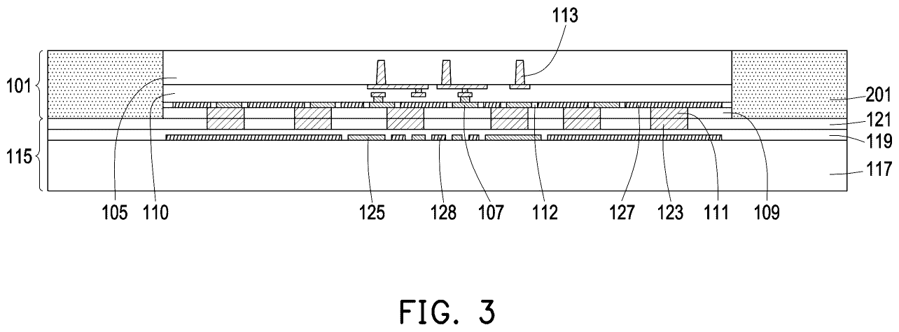

Once the first pads 107 and the first set of dummy pads 127 have been formed, the first bond layer 109 is formed over the first pads 107 and the first set of dummy pads 127. In an embodiment, the first bond layer 109 may be used for fusion bonding (also referred to as oxide-to-oxide bonding) or as part of a hybrid bond (described further below with respect to FIG. 3). In accordance with some embodiments, the first bond layer 109 is formed of a silicon-containing dielectric material such as silicon oxide, silicon nitride, or the like. The first bond layer 109 may be deposited using any suitable method, such as CVD, high-density plasma chemical vapor deposition (HDPCVD), PVD, atomic layer deposition (ALD), or the like, to a thickness of between about 0.65 μm and about 6 μm, such as about 5.5 μm. However, any suitable materials, deposition processes, and thicknesses may be utilized.

Once formed, the first bond layer 109 may be planarized in order to provide a planar surface for further processing. In an embodiment the first bond layer 109 may be planarized using a planarization process such as CMP. However, any other suitable planarization process may also be used.

Once the first bond layer 109 has been formed, openings in the first bond layer 109 are formed to expose conductive portions of the underlying layers in preparation to form a bond pad via (not separately illustrated in FIG. 1A for clarity). In an embodiment a photoresist is applied over top surfaces of the first bond layer 109 and the photoresist is then used along with one or more etches to etch the first bond layer 109 in order to form the openings. The etches used to form the openings may include dry etching (e.g., RIE or NBE), wet etching, or the like. In accordance with some embodiments of the present disclosure, the etching stops on the first pads 107 such that the conductive portions of the underlying layers are exposed through the openings in the first bond layer 109. However, any suitable processes may be utilized.

Second openings in the first bond layer 109 are also utilized to widen portions of the openings in preparation for formation of the first bonding metal 111. In an embodiment another photoresist is applied over top surfaces of the first bond layer 109. The photoresist is patterned and is then used to etch the first bond layer 109 to form the second openings. The first bond layer 109 may be etched by dry etching (e.g., RIE or NBE), wet etching, or the like.

Once the openings and the second openings have been formed within the first bond layer 109, the openings and second openings may be filled with a seed layer and a plate metal to form the bond pad via and the first bonding metal 111 (with both of them being represented in FIG. 1A as a single structure but which may or may not be physically separated in a final structure). The seed layer may be blanket deposited over top surfaces of the first bond layer 109 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first bond layer 109 and sidewalls of the openings and the second openings before the seed layer. The barrier layer may comprise titanium, titanium nitride, tantalum, tantalum nitride, or the like.

Following the filling of the openings and the second openings, a planarization process, such as a CMP, is performed to remove excess portions of the seed layer and the plate metal, forming the bond pad via and the first bonding metal 111. In some embodiments the bond pad via is utilized to connect the first bonding metal 111 with the underlying first pads 107 and, through the underlying first pads 107, connect the first bonding metal 111 with the underlying metallization layers 110 as well as the active devices.

The first semiconductor device 101 may also additionally include a plurality of through silicon vias (TSVs) 113 that extend through the first substrate 105 of the first semiconductor device 101 so as to provide a quick passage of data signals. In an embodiment the through silicon vias 113 may be formed by initially forming through silicon via (TSV) openings into the first substrate 105 (e.g., prior to formation of the active devices). The TSV openings may be formed by applying and developing a suitable photoresist (not shown), and removing portions of the first substrate 105 that are exposed to the desired depth. The TSV openings may be formed so as to extend into the first substrate 105 at least further than the active devices formed within and/or on the first substrate 105, and may extend to a depth greater than the eventual desired height of the first substrate 105. Accordingly, while the depth is dependent upon the overall designs, the depth may be between about 20 μm and about 200 μm from the active devices on the substrates 105, such as a depth of about 50 μm from the active devices on the substrates 105.

Once the TSV openings have been formed within the first substrate 105, the TSV openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may alternatively be used. Additionally, the liner may be formed to a thickness of between about 0.1 μm and about 5 μm, such as about 1 μm.

Once the liner has been formed along the sidewalls and bottom of the TSV openings, a barrier layer (also not independently illustrated) may be formed and the remainder of the TSV openings may be filled with first conductive material. The first conductive material may comprise copper, although other suitable materials such as aluminum, alloys, doped polysilicon, combinations thereof, and the like, may alternatively be utilized. The first conductive material may be formed by electroplating copper onto a seed layer (not shown), filling and overfilling the TSV openings. Once the TSV openings have been filled, excess liner, barrier layer, seed layer, and first conductive material outside of the TSV openings may be removed through a planarization process such as chemical mechanical polishing (CMP), although any suitable removal process may be used.

FIG. 1A additionally illustrates a bonding of the first semiconductor device 101 to a first wafer 115. In an embodiment the first wafer 115 may be, depending upon the desired final device, a carrier wafer or an application processor wafer. In embodiments in which the first wafer 115 is a carrier wafer, the first wafer 115 is intended to be supply structural support for the first semiconductor device 101 during subsequent processing, and may or may not be removed at a later stage of manufacture. In embodiments in which the first wafer 115 is an application processor wafer, the first wafer 115 is formed to work in conjunction with the first semiconductor device 101. However, any suitable functionality, such as additional memory or other functionality, may also be utilized.

In embodiments in which the first wafer 115 is a carrier wafer, the first wafer 115 may comprise a second substrate 117 which may be similar to the first substrate 105. For example, the second substrate 117 may be a semiconductor substrate. Additionally the first wafer 115 may also comprise a second bond layer 121. For example, the second bond layer 121 may be formed as a dielectric layer intended for fusion bonding to the first semiconductor device 101 (described further below).

In embodiments in which the first wafer 115 is a device formed to work in conjunction with the first semiconductor device 101, the first wafer 115 may comprise the second substrate 117 along with second active devices (not separately illustrated in FIG. 1A). In an embodiment the second substrate 117 and the second active devices may be similar to the first substrate 105 and the first active devices described above. For example, the second substrate 117 may be a semiconductor substrate and the second active devices may be active and passives devices formed on or in the second substrate 117. However, any suitable substrate and active devices may be utilized.

The first wafer 115 may also comprise a second metallization layer 119, second pads 125, a second set of dummy pads 128, a second bond layer 121, and second bond metal 123. In one embodiment, the second metallization layer 119, the second bond layer 121, the second set of dummy pads 128, the second pads 125 and the second bond metal 123 may be similar to the first metallization layer 110, the first bond layer 109, the first set of dummy pads 127, the first pads 107, and the first bond metal 111 as described above. For example, the second bond metal 123 may be a metal placed into the second bond layer 121 after the second bond layer 121 has been formed.

Once the second bond layer 121 and the second bond metal 123 have been formed, the first semiconductor device 101 may be bonded to the first wafer 115. In an embodiment the first semiconductor device 101 may be bonded to the first wafer 115 using, e.g., a fusion bonding process (in embodiments in which the first wafer 115 is a carrier wafer and the dielectric material of the second bond layer 121 covers the surface of the first wafer 115) or a hybrid bonding process (in embodiments in which the first wafer 115 is an active wafer and the surface comprises both the second bond layer 121 and the second bond metal 123). In an embodiment in which a hybrid bonding process is utilized, the first bond layer 109 is bonded to the second bond layer 121 and the first bond metal 111 is bonded to the second bond metal 123. In this embodiment the top surfaces of the first wafer 115 and the first semiconductor device 101 may first be activated utilizing, e.g., a dry treatment, a wet treatment, a plasma treatment, exposure to an inert gas, exposure to H₂, exposure to N₂, exposure to O₂, or combinations thereof, as examples. However, any suitable activation process may be utilized.

After the activation process the first wafer 115 and the first semiconductor device 101 may be cleaned using, e.g., a chemical rinse, and then the first semiconductor device 101 is aligned and placed into physical contact with the first wafer 115. The first wafer 115 and the first semiconductor device 101 are then subjected to thermal treatment and contact pressure to hybrid bond the first wafer 115 to the first semiconductor device 101. For example, the first wafer 115 and the first semiconductor device 101 may be subjected to a pressure of about 200 kPa or less, and a temperature between about 25° C. and about 250° C. to fuse the first bond layer 109 and the second bond layer 121. The first wafer 115 and the first semiconductor device 101 may then be subjected to a temperature at or above the eutectic point for material of the first bond metal 111 and the second bond metal 123, e.g., between about 150° C. and about 650° C., to fuse the metal bond pads. In this manner, fusion of the first wafer 115 and the first semiconductor device 101 forms a hybrid bonded device. In some embodiments, the bonded dies are baked, annealed, pressed, or otherwise treated to strengthen or finalize the bond.

Additionally, while the above description describes the first bonding metal 111 as being within the first bond layer 109 and the first bonding metal 111 being over the first metallization layer 110, this is intended to be illustrative and is not intended to be limiting. In yet other embodiments, the first wafer 115 may be bonded to the first semiconductor device 101 by direct surface bonding, metal-to-metal bonding, or another bonding process. A direct surface bonding process creates an oxide-to-oxide bond or substrate-to-substrate bond through a cleaning and/or surface activation process followed by applying pressure, heat and/or other bonding process steps to the joined surfaces. In some embodiments, the first wafer 115 and the first semiconductor device 101 are bonded by metal-to-metal bonding that is achieved by fusing conductive elements. Any suitable bonding process may be utilized.

FIG. 1B illustrates a top down view of the first pads 107 within the first semiconductor device 101 along line A-A′ in FIG. 1A within a single row. In this embodiment the first pads 107 are shaped in such a way as to help minimize stress that occurs during subsequent bonding processes. For example, in some embodiments the first pads 107 are shaped to avoid sharply angled corners, such that any corners that are present are no greater than about 45°. In a particular embodiment the first pads 107 are shaped as an octagon with a pad width Wₚ of between about 26 μm and about 80 μm, wherein each corner has an angle of about 45°. However, any suitable shape may be utilized.

In this embodiment adjacent ones of the first pads 107 are manufactured such that a first space is located between adjacent first pads 107. In a particular embodiment the first pads 107 may be formed so that the adjacent first pads 107 are arranged to have a first pitch P₁ of between about 100 μm and about 35 μm and so that the first pads 107 are separated from each other by a first distance D₁ of between about 9 μm and about 74 μm. However, any suitable pitch and distance may be utilized.

In the embodiment illustrated in FIG. 1B, the first space between the first pads 107 is at least partially filled with the first set of dummy pads 127 that stretch at least partially across the first space. In an embodiment the first set of dummy pads 127 comprise multiple, non-functional dummy pads with different shapes or dimensions, and in the embodiments illustrated in FIG. 1B, the first set of dummy pads 127 comprise first dummy pads 129, second dummy pads 131, and third dummy pads 133. In an embodiment the first dummy pads 129 are located directly between the first pads 107 so that no portion of the first dummy pads 129 extends either below or above the boundaries of the first pads 107 (in the view illustrated in FIG. 1B). In a particular embodiment the first dummy pads 129 may be rectangular in shape and may have a first width W₁ of between about 1.8 μm and about 20 μm and a first length L₁ of between about 1.8 μm and about 20 μm. However, any suitable shape and dimensions may be utilized.

In the embodiment illustrated in FIG. 1B there are three of the first dummy pads 129 with equal dimensions. In such an embodiment the first dummy pads 129 may be spaced apart from the first pads 107 by a second distance D₂ of between about 1.8 μm and about 2 μm. Further, the first dummy pads 129 may be spaced apart from each other by a third distance D₃ of between about 1.8 μm and about 6 μm. However, any suitable distances may be utilized.

Additionally, because the first pads 107 may be different shapes than simply square or rectangular, the second dummy pads 131 may also be rectangular and utilized in order to help fill the first space between the first pads 107. For example, in the illustrated embodiment in which the first pads 107 are octagonal and have chamfered corners, the second dummy pads 131 may be formed with larger dimensions than the first dummy pads 129 in order to expand further and take up additional space between the first pads 107. In a particular embodiment, the second dummy pads 131 may have a second width W₂ that is larger than the first distance D₁ (e.g., the distance between the first pads 107), such as a second width W₂ of between about 10 μm and about 12 μm, and have a second length L₂ of between about 1.8 μm and about 6 μm. However, any suitable dimensions may be utilized.

Finally, the third dummy pads 133 may be formed to separate the illustrated first pads 107 from additional first pads 107 in different rows (not separately illustrated in FIG. 1B but located above and below the first pads 107 illustrated in FIG. 1B). In the illustrated embodiment the third dummy pads 133 may be formed as a continuous line with a third width W₃ that is at least as large as the first pitch P₁, such as by being between about 35 μm and about 100 μm and a third length L₃ of between about 1.8 μm and about 10 μm. However, any suitable dimensions may be utilized.

By forming the first set of dummy pads 127 as described above, the first set of dummy pads 127 can help prevent issues related to the subsequent bonding process between the first semiconductor device 101 and the first wafer 115, especially in more advanced nodes. In particular, by forming the first set of dummy pads 127 to take up additional space between the first pads 107, the difference in expansion between the first pads 107 and the first pad dielectric 112 can be reduced. Such a reduction causes less interference in the subsequent bonding process, and leads to a reduction in defects during the bonding process.

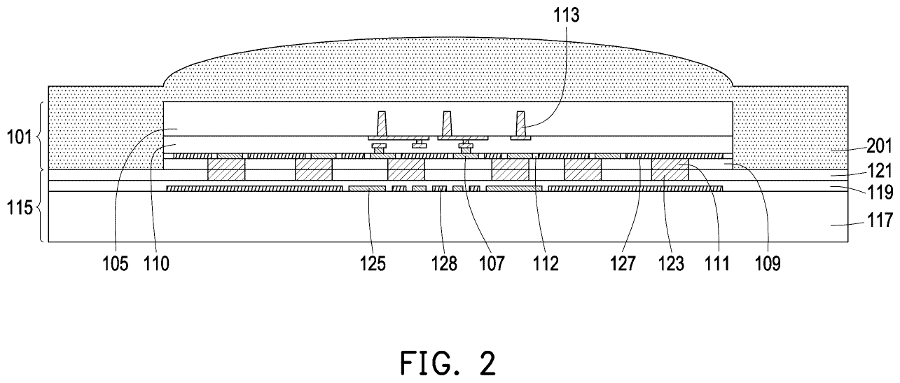

FIG. 2 illustrates deposition of a first gap-fill material 201 over the first semiconductor device 101 and the first wafer 115. In an embodiment, the first semiconductor device 101 can be encapsulated with the first gap-fill material 201. In some embodiments, the first gap-fill material 201 may comprise a non-polymer like silicon dioxide, silicon nitride, or the like, such as another oxide or nitride, which is deposited using any suitable process. For example, the first gap-fill material 201 may be formed by CVD, PECVD or ALD deposition process, FCVD, or a spin-on-glass process. However, any suitable material and any suitable deposition process may be utilized.

FIG. 3 illustrates that, once the first gap-fill material 201 has been deposited, the first gap-fill material 201 may be planarized and thinned in order to expose the first substrate 105. The thinning may be performed, e.g., using a mechanical grinding or CMP process whereby chemical etchants and abrasives are utilized to react and grind away the first gap-fill material 201 until the first substrate 105 has been exposed. As such, the first gap-fill material 201 and the first substrate 105 may have a planar surface with each other.

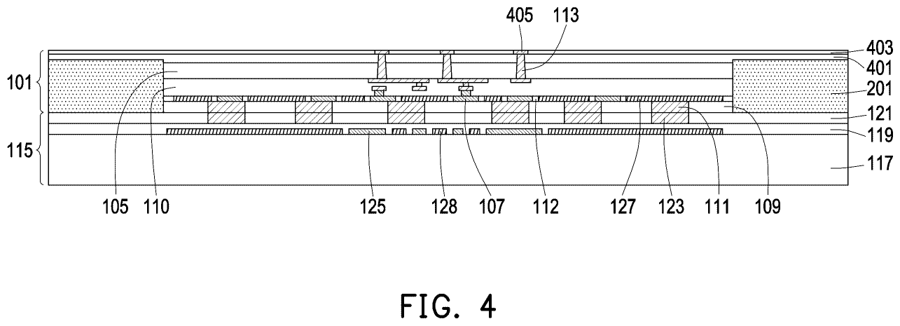

FIG. 4 illustrates an exposure of the TSVs 113, followed by deposition of a first dielectric material 401. In an embodiment, once the first substrate 105 has been exposed, the first substrate 105 may be further thinned by the planarization process (e.g., CMP) described above with respect to FIG. 3 until the TSVs 113 have been exposed. Further, once exposed, the TSVs 113 may be recessed using, e.g., one or more etching processes, such as a wet etch process in order to recess the first substrate 105 so that the TSVs 113 extend out of the first substrate 105.

Once the first substrate 105 has been recessed, the first dielectric material 401 is deposited and planarized. In an embodiment the first dielectric material 401 is a material such as silicon oxide, silicon nitride, silicon oxynitride, silicon carbon oxynitride, silicon carbide, silicon oxycarbide, combinations of these, or the like, deposited using a deposition process such as atomic layer deposition, chemical vapor deposition, sputtering, or the like. The first dielectric material 401 may then be planarized using a planarization process such as chemical mechanical polishing such that the first dielectric material 401 is planar and ready for further processing.

FIG. 4 additionally illustrates formation of a third bond layer 403 and third bonding metal 405 over the first dielectric material 401. In an embodiment the third bond layer 403 may be used for fusion bonding (also referred to as oxide-to-oxide bonding). In accordance with some embodiments, the third bond layer 403 is formed of a silicon-containing dielectric material such as silicon oxide, silicon nitride, or the like. The third bond layer 403 may be deposited using any suitable method, such as, CVD, high-density plasma chemical vapor deposition (HDPCVD), PVD, atomic layer deposition (ALD), or the like. The third bond layer 403 may be planarized, for example, in a chemical mechanical polish (CMP) process.

The third bonding metal 405 may be formed within the third bond layer 403 and in electrical contact with the TSVs 113. In an embodiment the third bonding metal 405 may be formed by first forming openings within the third bond layer 403 by first applying a photoresist over the top surface of the third bond layer 403 and patterning the photoresist. The photoresist is then used to etch the third bond layer 403 in order to form openings. The third bond layer 403 may be etched by dry etching (e.g., reactive ion etching (RIE) or neutral beam etching (NBE)), wet etching, or the like.

Once the openings have been formed, the openings within the third bond layer 403 are filled with the third bonding metal 405. In an embodiment the third bonding metal 405 may comprise a seed layer and a plate metal. The seed layer may be blanket deposited over top surfaces of the third bond layer 403, and may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the third bond layer 403 before the seed layer. The barrier layer may comprise titanium, titanium nitride, tantalum, tantalum nitride, or the like.

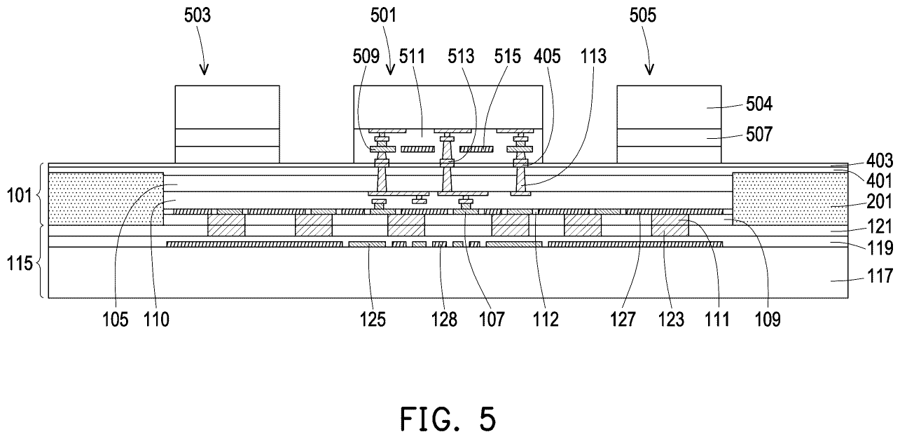

FIG. 5 illustrates a bonding of a second semiconductor device 501, a third semiconductor device 503, and a fourth semiconductor device 505 to the first semiconductor device 101. In an embodiment the second semiconductor device 501, the third semiconductor device 503, and the fourth semiconductor device 505 may be similar to the first semiconductor device 101 (e.g., a memory device, a logic device, a power device, etc.) that are designed to work in conjunction with the first semiconductor device 101 and with each other. However, any suitable functions may be utilized.

In an embodiment, each of the second semiconductor device 501, the third semiconductor device 503, and the fourth semiconductor device 505 may each comprise a third substrate 504, third active devices (not separately illustrated), third metallization layers 507, third pads 509, a fourth bond layer 511, and fourth bonding metal 513 within the fourth bond layer 511 (wherein many of these are illustrated within the second semiconductor device 501 but not in the third semiconductor device 503 and the fourth semiconductor device 505 for clarity). In such embodiments the third substrate 504, third active devices, third metallization layers 507, third pads 509, the fourth bond layer 511, and the fourth bonding metal 513 may be formed using similar materials and processes as the first substrate 105, the first active devices, the first metallization layers 110, first pads 107, the first bond layer 109, and the first bonding metal 111 as described above with respect to FIG. 1A.

The second semiconductor device 501, the third semiconductor device 503, and the fourth semiconductor device 505 may be bonded to the first semiconductor device 101 using similar processes as the bonding of the first semiconductor device 101 to the first wafer 115 as described above with respect to FIG. 1A. For example, the second semiconductor device 501, the third semiconductor device 503, and the fourth semiconductor device 505 may be bonded using, e.g., a hybrid bond wherein both dielectric and conductive elements are bonded together. However, any suitable bonding process may be utilized.

Further in this embodiment, the third pads 509 are surrounded by a third set of dummy pads 515. In an embodiment the third set of dummy pads 515 may be similar to the first set of dummy pads 127 (described above with respect to FIG. 1B), such as by having multiple different types of dummy pads with different dimensions. However, any suitable types of dummy pads may be utilized.

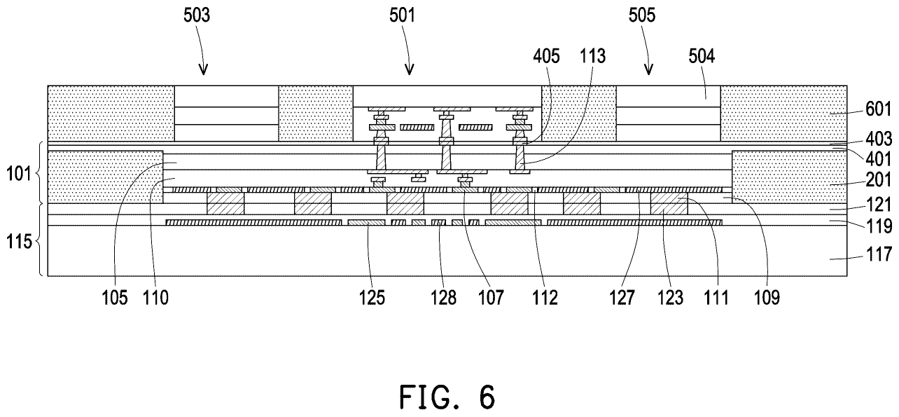

FIG. 6 illustrates a deposition of a second gap-fill material 601 to encapsulate the second semiconductor device 501, the third semiconductor device 503, and the fourth semiconductor device 505. In some embodiments, the second gap-fill material 601 may comprise a non-polymer like silicon dioxide, silicon nitride, or the like, such as another oxide or nitride, which is deposited using any suitable process. For example, the second gap-fill material 601 may be formed by CVD, PECVD or ALD deposition process, FCVD, or a spin-on-glass process. However, any suitable material and any suitable deposition process may be utilized.

FIG. 6 additionally illustrates that, once the second gap-fill material 601 has been deposited, the second gap-fill material 601 may be planarized and thinned in order to expose the third substrates 504 within the second semiconductor device 501, the third semiconductor device 503, and the fourth semiconductor device 505. The thinning may be performed, e.g., using a mechanical grinding or CMP process whereby chemical etchants and abrasives are utilized to react and grind away the second gap-fill material 601 until the third substrates 504 within the second semiconductor device 501, the third semiconductor device 503, and the fourth semiconductor device 505 have been exposed. As such, the second gap-fill material 601 and the third substrates 504 may have a planar surface with each other.

By utilizing the first set of dummy pads 127, the second set of dummy pads 128, and the third set of dummy pads 515, defects in the bonding process caused by uneven expansions of the pads can be reduced or eliminated. In particular, by reducing the problems related to the expansions of the pads, other problems related to the bonding of the overlying layers can be reduced. As such, the overall yield of the manufacturing process can be increased.

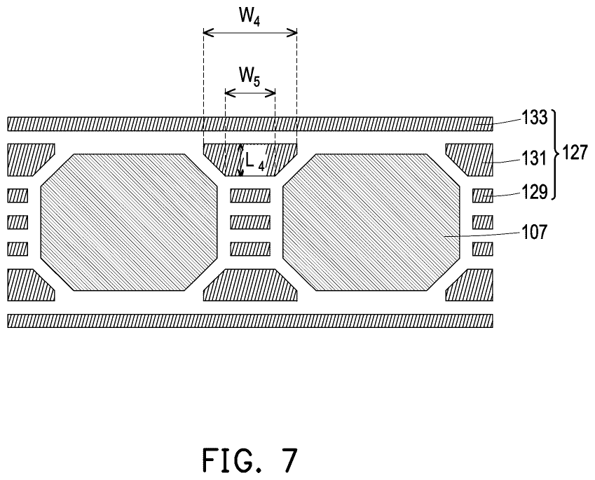

FIG. 7 illustrates another embodiment in which the first set of dummy pads 127 utilizes each of the first dummy pads 129, the second dummy pads 131, and the third dummy pads 133. In this embodiment, however, while the first dummy pads 129 and the third dummy pads 133 are kept in their previously described rectangular shapes or line shapes, the second dummy pads 131 are reshaped to better conform to the shape of the first pads 107 when the first pads 107 are not rectangular. For example, in the illustrated embodiment in which the first pads 107 have an octagonal shape with chamfered sides, the second dummy pads 131 can be reshaped to also have chamfered sides. As such, the second dummy pads 131 can take up more space between the first pads 107.

In this embodiment the second dummy pads 131 may have a fourth length L₄ of greater than or equal to about 1.8 μm and less than or equal to about 10 μm. Additionally, given the chamfered edges of the second dummy pads 131 in this embodiment, the second dummy pads 131 may have at least two widths, such as having a fourth width W₄ along a first side of the second dummy pads 131 and a fifth width W₅ shorter than the fourth width W₄ along a second side of the second dummy pads 131. In a particular embodiment the fourth width W₄ may be greater than or equal to about 1.8 μm and less than or equal to about 20 μm, while the fifth width W₅ may be between about 8 μm and about 10 μm. However, any suitable dimensions may be utilized.

By forming the second dummy pads 131 with the chamfered corners, the second dummy pads 131 can fill more of the space between adjacent first pads 107 than if the second dummy pads 131 has a simple rectangular shape. For example, the first set of dummy pads 127, as described, may be used to ensure that the first pads 107 are separated from the first set of dummy pads 127 by between about 1.8 μm and about 2.25 μm. As such, by filling more of the space, there are fewer issues related to the expansion of the first pads 107, leading to further reductions in issues during the subsequent bonding processes. Accordingly, the overall yield of the manufacturing process may be increased.

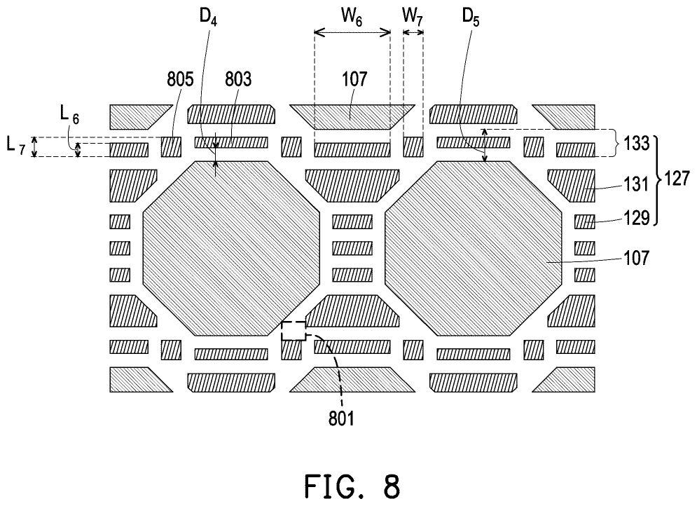

FIG. 8 illustrates yet another embodiment of the first set of dummy pads 127 which uses the second dummy pads 131 that have been reshaped to have a chamfered edge (as described above with respect to FIG. 7) while the first dummy pads 129 retain their rectangular shape (as described above with respect to FIG. 1B). In this embodiment, the third dummy pads 133, instead of being a continuous line, are instead formed as a series of discontinuous dummy pads, such as a first discontinuous dummy pad 803 and a second discontinuous dummy pad 805. In an embodiment the first discontinuous dummy pads 803 and the second discontinuous dummy pads 805 are located off-center from each others' centerlines in order to allow for closer spacing between the first pads 107 in different rows.

For example, in an embodiment the first discontinuous dummy pads 803 may be rectangular in shape and may have a sixth width W₆ of between about 5 μm and about 20 μm and a sixth length L₆ of between about 1.8 μm and about 10 μm. Additionally, the first discontinuous dummy pads 803 may be spaced a fourth distance D₄ from a nearest one of the first pads 107 of between about 1.8 μm and about 10 μm. However, any suitable dimensions may be utilized.

The second discontinuous dummy pads 805 are located between the first discontinuous dummy pads 803. In the illustrated embodiment the second discontinuous dummy pads 805 are square in shape and have a seventh width W₇ of between about 1.8 μm and about 10 μm, and a seventh length L of between about 1.8 μm and about 10 μm. However, any suitable dimensions may be utilized.

Additionally, in order to make room for the reduced distance between first pads 107, the sixth width W₆ of the first discontinuous dummy pads 803 may be less than the seventh width W₇ of the second discontinuous dummy pads 805, and the sixth length L₆ may be less than the seventh length L₇. As such, centerlines of the first discontinuous dummy pads 803 may be offset from centerlines of the second discontinuous dummy pads 805. Accordingly, while the first discontinuous dummy pads 803 and the second discontinuous dummy pads 805 may have one side aligned with each other, they both have sides that are offset from each other.

Because of this difference in lengths, the distance between first pads 107 that are not in the same row may be reduced. For example, a fifth distance D₅ between a top of one of the first pads 107 and a bottom of another one of the first pads 107 in an adjacent row may be reduced to be between about 1.8 μm and about 10 μm while still obtaining a reduction in stress of about 35% over embodiments without the first set of dummy pads 127. Additionally, by utilizing the second dummy pads 131 with the chamfered corners along with the first discontinuous dummy pads 803 and the second discontinuous dummy pads 805, the remaining region (illustrated by the dashed box labeled 801) between the first pads 107 and the first set of dummy pads 127 can be reduced to an area of less than 4 μm wide by 4 μm long. As such, by reducing the distance between first pads 107 in adjacent rows, the overall spacings may be reduced, allowing for a smaller overall device.

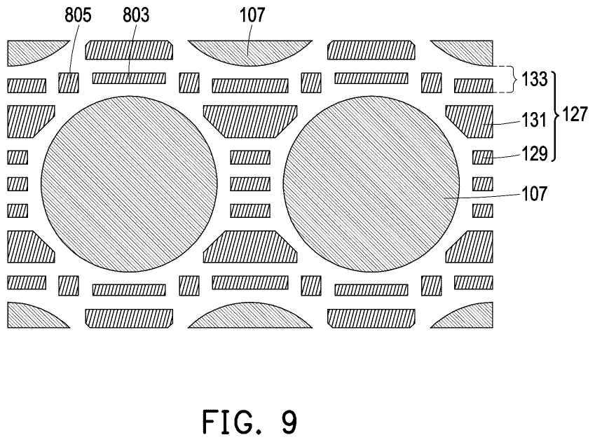

FIG. 9 illustrates yet another embodiment in which the first dummy pads 129 remain as rectangles, the second dummy pads 131 remain with chamfered edges, and the third dummy pads 133 comprise the first discontinuous dummy pads 803 and the second discontinuous dummy pads 805. In this embodiment, however, the first pads 107, instead of being octagonal in shape as described above, are circular in shape. However, even with the difference in shape, the first set of dummy pads 127 are able to help fill the regions between the first pads 107 so that undesired results during the bonding process are reduced or minimized. In particular, when forming the first pads 107 as circles, the first set of dummy pads 127 can result in about a 36% reduction in stress over embodiments which do not use the first set of dummy pads 127.

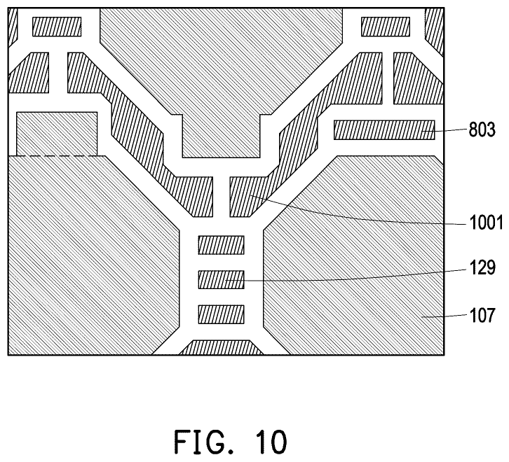

FIG. 10 illustrates a further embodiment that allows for reduction in the defects caused by the first pads 107 during bonding processes. In the specific embodiment illustrated in FIG. 10, the first pads 107, instead of being symmetrical around its perimeter (as in, e.g., an octagonal or circular shape), may be asymmetrical. For example, as illustrated in FIG. 10, the first pads 107 may have an octagonal part while also having a square extension along one side (shown in FIG. 10 as being separated by a dashed line but in which there may be no visible difference in the actual product). As such, the first pads 107 may be placed in an interlocking pattern with each other.

In such an embodiment, instead of modifying the third dummy pads 133 into the first discontinuous dummy pad 803 and the second discontinuous dummy pads 805, the first discontinuous dummy pads 803 are retained while the second discontinuous dummy pads 805 (as described above with respect to FIG. 8) and the second dummy pads 131 are merged into an “S”-shaped dummy pad 1001 that roughly follows the contours between adjacent ones of the first pads 107. As such, the sides of the “S”-shaped dummy pad 1001 run parallel with sides of the first pads 107 which they face.

By using the “S”-shaped dummy pad 1001, additional space between the first pads 107 may be taken up and the stress may be reduced by 12% over embodiments which utilize a rectangular first pad 107 and rectangular dummy pads. For example, in using the illustrated embodiment, the first set of dummy pads 127 may be formed such that there is no more than between 1.8 μm to 2.04 μm distance between the sidewalls of the first set of dummy pads 127 and the closest surrounding structures (e.g., the first pads 107 or the other dummy pads 127). By reducing this distance even further, the reduction in defects caused by the expansion of the first pads 107 during the subsequent bonding processes can be further reduced.

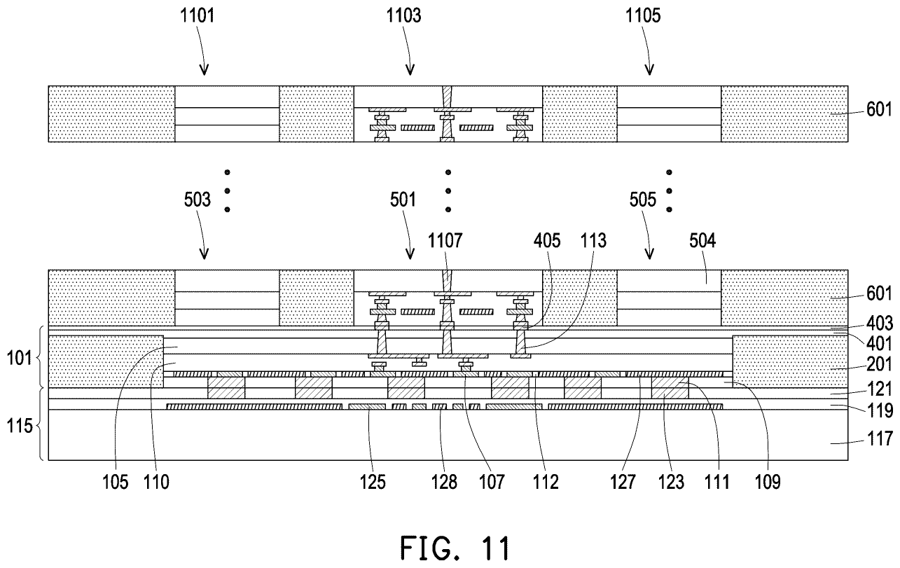

FIG. 11 illustrates another embodiment that, instead of stopping after bonding and encapsulating the second semiconductor device 501, the third semiconductor device 503, and the fourth semiconductor device 505, keeps going and bonds a fifth semiconductor device 1101, a sixth semiconductor device 1103, and a seventh semiconductor device 1105 to the second semiconductor device 501, the third semiconductor device 503, and the fourth semiconductor device 505, respectively. In this embodiment the second semiconductor device 501, the third semiconductor device 503, and the fourth semiconductor device 505 may be manufactured with second through substrate vias 1107 (only one of which is illustrated in FIG. 11 for clarity). In an embodiment the second through substrate vias 1107 may be formed using similar processes and materials as the TSVs 113 (described above with respect to FIG. 1A). However, any suitable processes and materials may be utilized.

Additionally, the fifth semiconductor device 1101, the sixth semiconductor device 1103, and the seventh semiconductor device 1105 may be similar to the second semiconductor device 501, the third semiconductor device 503, and the fourth semiconductor device 505, respectively. For example, the fifth semiconductor device 1101, the sixth semiconductor device 1103, and the seventh semiconductor device 1105 may be semiconductor dies manufactured to work in conjunction with the second semiconductor device 501, the third semiconductor device 503, and the fourth semiconductor device 505. However, any suitable device and/or functionality may be utilized.

In an embodiment the fifth semiconductor device 1101, the sixth semiconductor device 1103, and the seventh semiconductor device 1105 may be bonded by repeating the steps described above with respect to FIGS. 5 and 6. For example, the fifth semiconductor device 1101, the sixth semiconductor device 1103, and the seventh semiconductor device 1105 may be aligned with the second through substrate vias 1107, bonded using, e.g., a hybrid bonding process, and then encapsulated with the second gap-fill material 601 in order to provide protection. However, any suitable bonding process may be utilized.

Additionally in this embodiment, one or more, or each, of the fifth semiconductor device 1101, the sixth semiconductor device 1103, and the seventh semiconductor device 1105 are manufactured to include the third set of dummy pads 515 (using any of the embodiments described herein) around the third pads 509. As such, defects caused by the elevated temperatures during the bonding process can be mitigated or eliminated by helping to relieve stress.

Additionally, if desired, these steps may be repeated as many times as desired. As such, a semiconductor device with any desired number of layers of devices may be obtained. All such numbers of layers are fully intended to be included within the scope of the embodiments.

By utilizing the first set of dummy pads 127 around the first pads 107 (and/or the second set of dummy pads 128, third set of dummy pads 515, etc.), defects that occur during subsequent bonding processes can be mitigate or eliminated. In particular, by reducing mismatches between materials within the layer comprising the first pads 107, the stresses can be reduced, thereby causing fewer defects when these stresses are increased during times of elevated temperatures, such as during the bonding processes. By reducing these stresses, these stresses do not interfere as much with the bonding process, thereby leading to fewer defects in the bonding process itself, leading to an overall increased yield during the manufacturing process.

In accordance with an embodiment, a method of manufacturing a semiconductor device includes: forming a first pad over a semiconductor substrate; forming a second pad adjacent to the first pad; forming a first set of dummy pads at least partially between the first pad and the second pad; and depositing a bonding dielectric material over the first pad, the second pad, and the first set of dummy pads. In an embodiment the forming the first set of dummy pads comprises forming first dummy pads and second dummy pads between the first pad and the second pad, the second dummy pads having a larger width than the first dummy pads. In an embodiment the second dummy pads have a larger width than a distance between the first pad and the second pad. In an embodiment the forming the first dummy pads and the second dummy pads forms the second dummy pads having chamfered corners. In an embodiment the forming the first set of dummy pads forms a third dummy pad adjacent to one of the second dummy pads, the third dummy pad being a continuous line. In an embodiment the forming the first set of dummy pads forms a third dummy pad adjacent to one of the second dummy pads, the third dummy pad being a discontinuous line.

In accordance with another embodiment, a method of manufacturing a semiconductor device includes: forming a first pad and a second pad over a metallization layer; forming a first set of dummy pads around the first pad and the second pad, the first set of dummy pads including: a first dummy pad between the first pad and the second pad, the first dummy pad being rectangular in shape; a second dummy pad between the first pad and the second pad, the second dummy pad being wider than the first dummy pad; a third dummy pad on an opposite side of the second dummy pad from the first dummy pad, the third dummy pad having a different width than the second dummy pad; and forming a bonding layer over the first pad and the second pad, the bonding layer comprising a conductive bond pad in electrical connection with the first pad. In an embodiment the method further includes bonding the bonding layer to a second bonding layer. In an embodiment the bonding the bonding layer forms a hybrid bond. In an embodiment the bonding the bonding layer forms a fusion bond. In an embodiment the third dummy pad is discontinuous. In an embodiment different portions of the third dummy pad have centerlines that are off-center from each other. In an embodiment the second dummy pad has a first chamfered corner. In an embodiment the first pad has a second chamfered corner.

In accordance with yet another embodiment, a semiconductor device includes: metallization layers over a semiconductor substrate; a first pad separated from a second pad over the metallization layers; a first dummy pad between the first pad and the second pad; and a second dummy pad at least partially between the first pad and the second pad, the second dummy pad having a width larger than a shortest distance between the first pad and the second pad. In an embodiment the second dummy pad is in an “S”-shape. In an embodiment the first pad and the second pad have a pitch of about 35 μm. In an embodiment the second dummy pad has at least one chamfered corner. In an embodiment the semiconductor device further includes a third dummy pad on an opposite side of the second dummy pad from the first dummy pad, the third dummy pad being discontinuous. In an embodiment the first pad is circular.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first pad over a semiconductor substrate;
a second pad adjacent to the first pad;
a first set of dummy pads at least partially between the first pad and the second pad; and
a bonding dielectric material over the first pad, the second pad, and the first set of dummy pads.

2. The semiconductor device of claim 1, wherein the first set of dummy pads comprises first dummy pads and second dummy pads between the first pad and the second pad, the second dummy pads having a larger width than the first dummy pads.

3. The semiconductor device of claim 2, wherein the second dummy pads have a larger width than a distance between the first pad and the second pad.

4. The semiconductor device of claim 3, wherein the second dummy pads have chamfered corners.

5. The semiconductor device of claim 4, wherein the first set of dummy pads comprises a third dummy pad adjacent to one of the second dummy pads, the third dummy pad being a continuous line.

6. The semiconductor device of claim 4, wherein the first set of dummy pads comprises a third dummy pad adjacent to one of the second dummy pads, the third dummy pad being a discontinuous line.

7. A semiconductor device comprising:
a first pad and a second pad over a metallization layer;
a first set of dummy pads around the first pad and the second pad, the first set of dummy pads comprising:
a first dummy pad between the first pad and the second pad, the first dummy pad being rectangular in shape;
a second dummy pad between the first pad and the second pad, the second dummy pad being wider than the first dummy pad;
a third dummy pad on an opposite side of the second dummy pad from the first dummy pad, the third dummy pad having a different width than the second dummy pad; and
a bonding layer over the first pad and the second pad, the bonding layer comprising a conductive bond pad in electrical connection with the first pad.

8. The semiconductor device of claim 7, wherein the bonding layer is bonded to a second bonding layer.

9. The semiconductor device of claim 8, wherein the bonding layer is bonded to the second bonding layer with a hybrid bond.

10. The semiconductor device of claim 8, wherein the bonding layer is bonded to the second bonding layer with a fusion bond.

11. The semiconductor device of claim 7, wherein the third dummy pad is discontinuous.

12. The semiconductor device of claim 11, wherein different portions of the third dummy pad have centerlines that are off-center from each other.

13. The semiconductor device of claim 7, wherein the second dummy pad has a first chamfered corner.

14. The semiconductor device of claim 13, wherein the first pad has a second chamfered corner.

15. A semiconductor device comprising:
metallization layers over a semiconductor substrate;
a first pad separated from a second pad over the metallization layers;
a first dummy pad between the first pad and the second pad; and
a second dummy pad at least partially between the first pad and the second pad, the second dummy pad having a width larger than a shortest distance between the first pad and the second pad.

16. The semiconductor device of claim 15, wherein the second dummy pad is in an “S”-shape.

17. The semiconductor device of claim 15, wherein the first pad and the second pad have a pitch of about 35 μm.

18. The semiconductor device of claim 15, wherein the second dummy pad has at least one chamfered corner.

19. The semiconductor device of claim 15, further comprising a third dummy pad on an opposite side of the second dummy pad from the first dummy pad, the third dummy pad being discontinuous.

20. The semiconductor device of claim 15, wherein the first pad is circular.
